(19) United States
(12) Patent Application Publication
(10) Pub. No.: US 2015/0101852 A1
(43) Pub. Date: Apr. 16, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Jong Tae PARK, Suwon-Si (KR); Ho Shik Kang, Suwon-Si (KR)

(73) Assignee: SAMSUNG ELECTRO-MECHANICS CO., LTD., Suwon-Si (KR)

(21) Appl. No.: 14/499,184

(22) Filed: Sep. 28, 2014

(30) Foreign Application Priority Data
Oct. 14, 2013 (KR) 10-2013-0122126

(51) Int. Cl. H05K 1/11; H05K 3/04; H05K 1/09

(52) U.S. Cl. CPC H05K 1/115; H05K 1/092; H05K 3/048; H05K 2201/0104; H05K 2201/09818; H05K 2201/09563
USPC 174/258; 29/852; 216/17

(57) ABSTRACT

Disclosed herein are a printed circuit board and a method of manufacturing the same.

The printed circuit board according to a preferred embodiment of the present invention may include: an insulating layer; a first via depressed from one surface of the insulating layer; a second via depressed from the other surface of the insulating layer; and a circuit pattern formed in the insulating layer and bonded to the first and second vias.

### CROSS REFERENCE TO RELATED APPLICATION

This application claims the benefit of Korean Patent Application No. 10-2013-0122126, filed on Oct. 14, 2013, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

Recently, a trend of multifunctional and high-speed electronic products has rapidly progressed. In order to cope with this trend, a semiconductor chip and a printed circuit board mounted with the semiconductor chip have also been very rapidly developed. In the printed circuit board as described above, slimness and lightness, a fine circuit, excellent electric properties, high reliability, and high-speed signal transferring, and the like, are required.

According to the prior art, a core board including a core layer inserted therein to thereby prevent a warpage phenomenon of the printed circuit board has been mainly used (US Patent Application Publication No. 20040058136). However, a thickness of the core board is thick and a signal processing time thereof is long.

In addition, as electronic products such as a smart device, and the like, become thin, thinness of products mounted therein has also been required.

### SUMMARY OF THE INVENTION

The present invention has been made in an effort to provide an ultra-thin printed circuit board using a carrier board, and a method of manufacturing the same.

In addition, the present invention has been made in an effort to provide a printed circuit board capable of preventing dimple generation, and a method of manufacturing the same.

Further, the present invention has been made in an effort to provide a printed circuit board capable of forming a via on a circuit pattern to prevent the circuit pattern from being lost by an etching process, and a method of manufacturing the same.

According to a preferred embodiment of the present invention, there is provided a printed circuit board including: an insulating layer; a first via depressed from one surface of the insulating layer; a second via depressed from the other surface of the insulating layer; and a circuit pattern formed in the insulating layer and bonded to the first and second vias.

The second via may be depressed so as to have a depth deeper than that of the first via.

The first via and the circuit pattern may further include a seed layer, and the seed layer may be formed at a side of the first via and a portion contacting the insulating layer on one surface of the circuit pattern bonded to the first via.

The seed layer formed at a bottom of the first via.

A depression depth of the second via may be greater than or equal to a thickness of the seed layer of the first via.

The insulating layer may be made of a photosensitive insulating material.

The insulating layer may be made of a solder resist.

The first and second vias and the circuit pattern may be made of a conductive metal.

The first via and the circuit pattern may be made of a conductive metal, and the second via may be formed of a conductive paste.

According to another preferred embodiment of the present invention, there is provided a method of manufacturing a printed circuit board, the method including: forming a first insulating layer including a patterned first via hole on a carrier board; forming a plating resist including a patterned circuit pattern hole on the first insulating layer; forming a first via and a circuit pattern on the first via hole and circuit pattern hole using a conductive material; removing the plating resist; forming a patterned second insulating layer so that the circuit pattern is embedded therein and the second via hole is positioned on the circuit pattern; forming a second via on the second via hole using a conductive material; and removing the carrier board.

The first and second insulating layers may be made of a photosensitive insulating material.

The first and second insulating layers may be made of a solder resist.

The method may further include, after the forming of the first insulating layer, forming a seed layer on the first insulating layer and first via hole.

The method may further include, after the removing of the plating resist, removing the seed layer exposed by removal of the plating resist.

The method may further include, after the removing of the carrier board, removing the seed layer exposed by removal of the carrier board.

In the removing of the seed layer, the second via may be etched to thereby be removed by a thickness greater than or equal to a thickness of the removed seed layer.

In the removing of the seed layer, the first via may be formed so as to be depressed in the first insulating layer, and the second via may be formed so as to be depressed in the second insulating layer.

In the forming of the first insulating layer, the first insulating layer may be formed on one surface or both surfaces of the carrier board.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a printed circuit board according to a preferred embodiment of the present invention; and

FIGS. 2 to 11 are views showing a method of manufacturing a printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

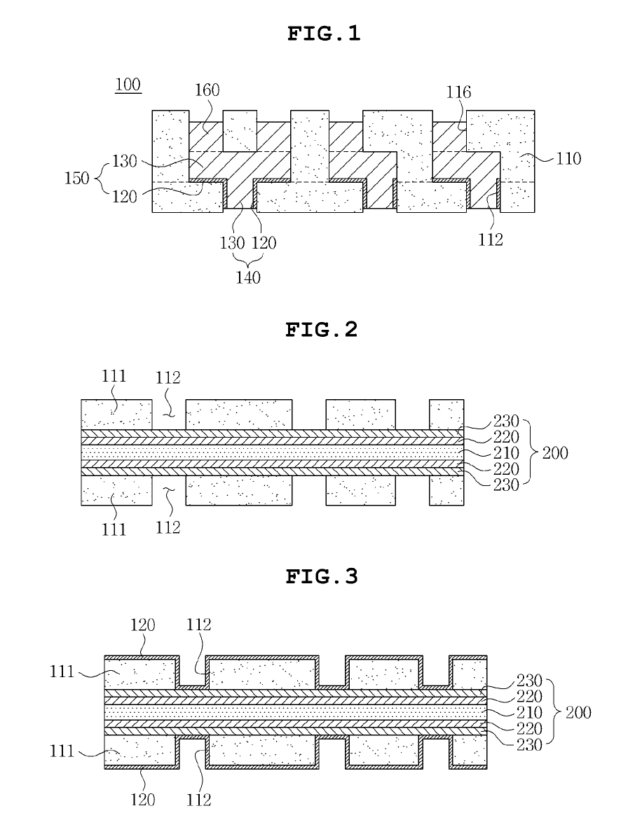

FIG. 1 shows a printed circuit board according to a preferred embodiment of the present invention.

Referring to FIG. 1, the printed circuit board 100 may be a single layer circuit board having a single layer circuit pattern.

The printed circuit board according to the preferred embodiment of the present invention may include an insulating layer 110, a first via 140, a circuit pattern 150, and a second via 160.

The insulating layer 110 may be made of a composite polymer resin generally used as an interlayer insulating material or a solder resist. For example, the insulating layer 110 may be made of for example, a prepreg, Ajinomoto build up film (ABF), or an epoxy based resin such as FR-4, a bismaleimide triazine (BT), or the like. In addition, the insulating layer 110 may be formed in a board or film shape. Further, the insulating layer 110 may be made of a photosensitive insulating material. However, a material forming the insulating layer 110 and a shape of the insulating layer 110 are not limited thereto. That is, any material and any shape used as an interlayer insulating material or a solder resist in a circuit board field may be applied to the insulating layer 110 according to the preferred embodiment of the present invention.

In the preferred embodiment of the present invention, the insulating layer 110 may be embedded with the first via 140, the circuit pattern 150, and the second via 160.

The first via 140 may be formed in one surface of the insulating layer 110. In addition, the first via 140 may be formed so as to be depressed from one surface of the insulating layer 110. The first via 140 may further include a seed layer 120 formed at a side thereof That is, the first via 140 may include the seed layer 120 formed by an electroless plating method and a plating layer 130 formed by an electroplating method.

In the preferred embodiment of the present invention, the first via 140 may be depressed from one surface of the insulating layer 110 so as to have a depth greater than or equal to a thickness of the seed layer 120.

The circuit pattern 150 may be formed on the other surface of the first via 140. That is, the circuit pattern 150 may be formed so as to be embedded in the insulating layer 110. The seed layer 120 may be further formed on one surface of the circuit pattern 150. Here, one surface of the circuit pattern 150 is a surface bonded to the other surface of the first via 140, and a portion at which the seed layer 120 is formed is a portion contacting the insulating layer 110. That is, the circuit pattern 150 may include the seed layer 120 formed by an electroless plating method and the plating layer 130 formed by an electroplating method.

In the preferred embodiment of the present invention, one surface of the circuit pattern 150 may be bonded to the first via 140 and the other surface thereof may be bonded to the second via 160.

The first via 140 and the circuit pattern 150 may be made of a conductive metal such as copper. However, the material of the first via 140 and the circuit pattern 150 is not limited to copper. The first via 140 and the circuit pattern 150 may be made of any conductive metal used in the circuit board field.

The second via 160 may be formed on the other surface of the circuit pattern 150. In addition, the second via 160 may be formed so as to be depressed from the other surface of the insulating layer 110. The second via 160 may be made of a conductive metal or conductive paste. Here, as the conductive metal and the conductive paste, any conductive metal and any conductive paste in the circuit board field may be used. Here, the second via 160 may be formed on the circuit pattern 150 to thereby serve to fill a dimple space when a dimple is generated in the circuit pattern 150. That is, the second via 160 may prevent the dimple from being generated in the circuit pattern 150. In addition, the second via 160 may be formed on the circuit pattern 150 to thereby serve to prevent the circuit pattern 150 from being lost by an external process environment.

In the preferred embodiment of the present invention, the second via 160 may be depressed from the other surface of the insulating layer 110 so as to have a depth deeper than a depression depth of the first via 140. That is, the second via 160 may also be depressed so as to have a depth greater than or equal to the thickness of the seed layer 120.

FIGS. 2 to 11 show a method of manufacturing a printed circuit board according to the preferred embodiment of the present invention.

Referring to FIG. 2, a first insulating layer 111 may be formed on a carrier board 200.

The carrier board 200 may have a copper clad lamination structure. In the preferred embodiment of the present invention, the carrier board 200 may be composed of a carrier insulating layer 210, a carrier metal layer 220, and a seed metal layer 230. The carrier board 200 may have a structure in which the carrier metal layer 220 and the seed metal layer 230 are sequentially laminated on both surfaces of the carrier insulating layer 210. The carrier insulating layer 210 may be an epoxy resin or an epoxy resin impregnated with a reinforcement material. For example, the carrier insulating layer 210 may be made of a prepreg. In addition, the carrier metal layer 220 and the seed metal layer 230 may be made of a metal such as copper. The carrier metal layer 220 and the seed metal layer 230 may be separated from each other later. Although in the preferred embodiment of the present invention, the carrier board 200 may be composed of the carrier insulating layer 210, the carrier metal layer 220, and the seed metal layer 230, the structure of the carrier board 200 is not limited thereto. As the carrier board 200, any carrier board used in the circuit board field may be used.

In the preferred embodiment of the present invention, a problem generated due to a thin thickness at the time of manufacturing an ultra-thin single layer printed circuit board may be solved by using the carrier board 200. That is, the thickness of the printed circuit board may be always constantly maintained during the process by applying the carrier board 200. Therefore, at the time of manufacturing the ultra-thin printed circuit board, the process may proceed without generating damage that will be generated when the printed circuit board is caught or torn by equipment due to the thin thickness, or the like.

The first insulating layer 111 may be formed on both surfaces of the carrier board 200 formed as described above. The insulating layer 111 may be made of a composite polymer resin generally used as an interlayer insulating material or a solder resist. For example, the insulating layer 111 may be made of for example, a prepreg, Ajinomoto build up film (ABF), or an epoxy based resin such as FR-4, a bismaleimide triazine (BT) or the like. Further, the insulating layer 111 may be made of a photosensitive insulating material. However, a material of the first insulating layer 111 is not limited thereto, but any material used as an interlayer insulating material or a solder resist in the circuit board field may be used.

The first insulating layer 111 may include a first via hole 112. The first via hole 112 may be formed in a shape in which it penetrates through the insulating layer 111.

For example, the first via hole 112 may be formed by forming an etching resist including an opening part corresponding to the first via hole 112 on the first insulating layer and then performing the etching thereon. Alternatively, in the case in which the first insulating layer 111 is made of the photosensitive insulating material, the first via hole 112 may be formed by performing exposure and development.

Referring to FIG. 3, a seed layer 120 may be formed.

The seed layer 120 may be formed on the first insulating layer 111 and the first via hole 112. The seed layer 120 may be made of a conductive metal such as copper. A material of the seed layer 120 is not limited to copper, and any conductive metal used in the circuit board field may be used. The seed layer 120 may be formed by an electroless plating method. The seed layer 120 may be formed by any method known in the art such as a sputtering method, or the like, as well as the electroless plating method.

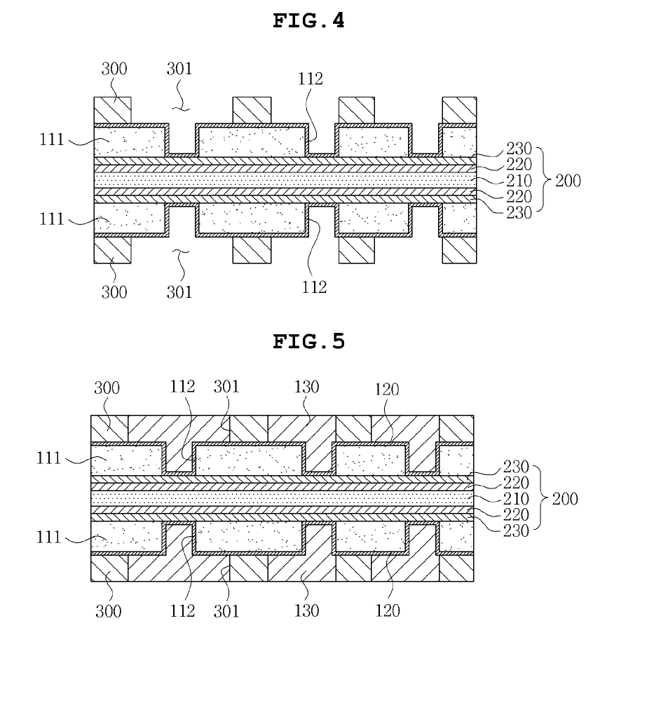

Referring to FIG. 4, a plating resist 300 may be formed on the seed layer 120.

The plating resist 300 may include an opening part 301. The opening part 301 of the plating resist 300 may be formed so that a region on which a circuit pattern (not shown) will be formed is exposed. In the preferred embodiment of the present invention, the opening part 301 of the plating resist 300 may be formed on the first via hole 112 of the first insulating layer 111.

Referring to FIG. 5, a plating layer 130 may be formed.

The plating layer 130 may be formed on the first via hole 112 of the first insulating layer 111 and the opening part 301 of the plating resist 300. The plating layer 130 may be made of a conductive metal such as copper. A material of the plating layer 130 is not limited to copper, and any conductive metal used in the circuit board field may be used. In addition, the plating layer 130 may be formed by an electroplating method. In this case, the seed layer 120 may serve as a lead line for forming the plating layer 130.

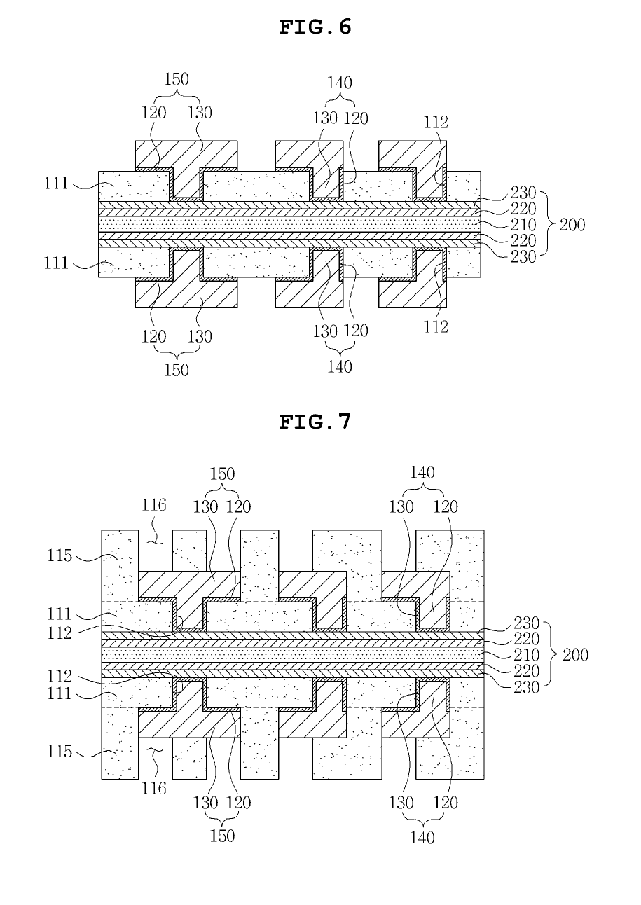

Referring to FIG. 6, the plating resist (300 in FIG. 6) and the seed layer 120 may be removed.

First, the plating resist (300 in FIG. 6) may be removed. Thereafter, the etching may be performed on the seed layer 120 exposed by removing the plating resist (300 in FIG. 6). A method of removing the seed layer 120 is not particularly limited, but the seed layer 120 may be removed by a general method known in the art. For example, the seed layer 120 may be etched by a quick etching method or a flash etching method.

The seed layer 120 is removed as described above, such that a circuit pattern 150 and a first via 140 may be formed. In the preferred embodiment of the present invention, the circuit pattern 150 may be composed of the seed layer 120 formed on the first insulating layer 111 and the plating layer 130.

In addition, the first via 140 may be composed of the seed layer 120 embedded in the first insulating layer 111 and the plating layer 130. The case in which the first via 140 is composed of the plating layer 130 and the seed layer 120 enclosing a side surface and a lower surface of the plating layer 130 is shown in FIG. 6. However, the seed layer 120 formed at the lower surface of the first via 140 may be removed later.

Referring to FIG. 7, a second insulating layer 115 may be formed.

The second insulating layer 115 may be formed so as to enclose the circuit pattern 150.

The second insulating layer 115 may be made of a composite polymer resin generally used as an interlayer insulating material or a solder resist. For example, the second insulating layer 115 may be made of for example, a prepreg, Ajinomoto build up film (ABF), or an epoxy based resin such as FR-4, a bismaleimide triazine (BT) or the like. Further, the second insulating layer 115 may be made of a photosensitive insulating material. However, a material of the second insulating layer 115 is not limited thereto, but any material used as an interlayer insulating material or a solder resist in the circuit board field may be used.

A second via hole 116 may be formed in the second insulating layer 115. The second via hole 116 may be formed at a region at which a second via (not shown) will be formed later. In the preferred embodiment of the present invention, the second via hole 116 may be formed on the circuit pattern 150.

The first and second insulating layers 111 and 115 may be made of the same material. The first and second insulating layers 111 and 115 according to the preferred embodiment of the present invention may become the insulating layer 110 shown in FIG. 1.

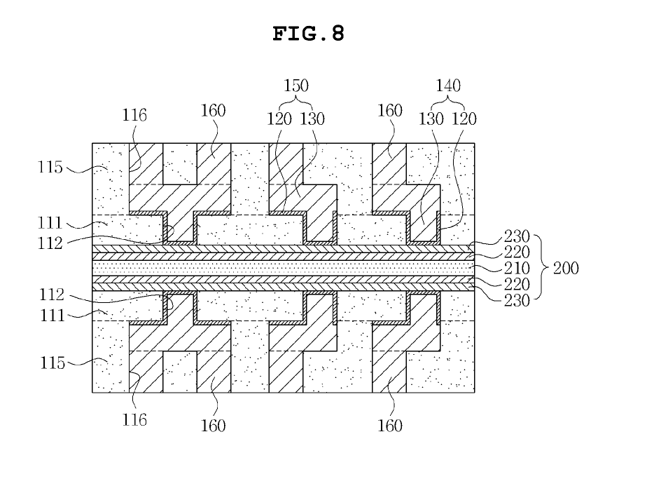

Referring to FIG. 8, a second via 160 may be formed.

The second via 160 may be formed by filling the second via hole 116. The second via 160 may be made of a conductive metal such as copper. Here, a material of the second via 160 is not limited to copper, and any conductive metal used in the circuit board field may be used. In addition, the second via 160 may be made of a conductive paste or conductive ink.

In the preferred embodiment of the present invention, the second via 160 may be formed in a method of filling the second via hole 116 formed on the circuit pattern 150. As the second via 160 is formed by filling the second via hole 116, it is possible to prevent a dimple from being formed in the circuit pattern 150. Therefore, a separate process (pretreatment, exposure, development, delamination, or the like) for preventing the dimple from being generated in the circuit pattern 150 may be omitted, such that production cost and time may be decreased.

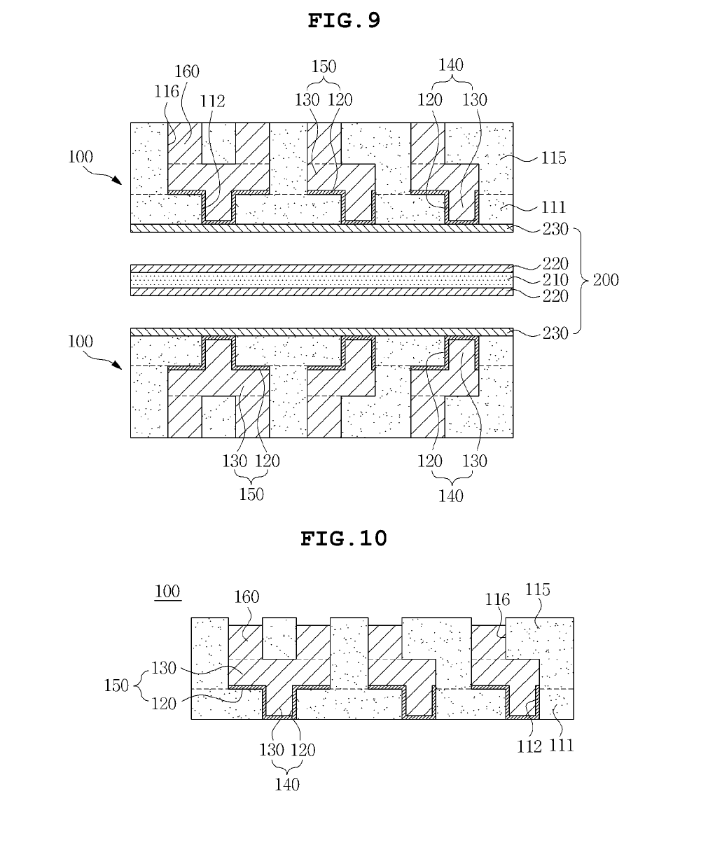

Referring to FIG. 9, the carrier board 200 may be removed.

The carrier metal layer 220 and the seed metal layer 230 of the carrier board 200 may be separated from each other. As the carrier metal layer 220 and the seed metal layer 230 are separated from each other, the printed circuit board 100 formed on both surfaces of the carrier board 200 may be separated from the carrier board 200.

According to the preferred embodiment of the present invention, two printed circuit boards 100 having a single layer may be simultaneously formed by using the carrier board 200.

Referring to FIG. 10, the seed metal layer 230 may be removed.

The printed circuit board 100 separated from the carrier board (200 in FIG. 9) may be a state in which the seed metal layer 230 is adhered thereto. The seed metal layer 230 adhered to the printed circuit board 100 may be removed by etching. In this case, the second via 160 may protect the circuit pattern 150 from an etching process at the time of etching the seed metal layer 230. Since the second via 160 is formed on the circuit pattern 150, the second via 160 instead of the circuit pattern 150 may be exposed to an etching process environment. When the metal seed layer 230 is etched, the second via 160 may protect the circuit pattern 150, and a surface of the second via exposed to the outside may be etched. Here, the second via 160 may be etched by a thickness of the seed metal layer 230. Therefore, the second via 160 may have a structure in which the second via 160 is depressed from the second insulating layer 115.

Only one of two printed circuit boards 100 is shown in FIG. 10. Since the printed circuit board 100 that is not shown is also subjected to the same process as that in the printed circuit board 100 shown in FIG. 10, drawings and description thereof will be omitted.

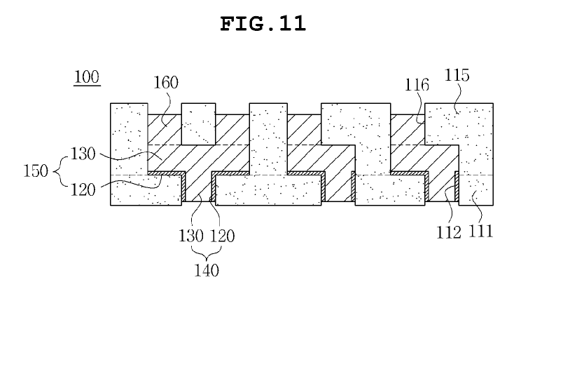

Referring to FIG. 11, the seed layer 120 may be removed.

After the seed metal layer (230 in FIG. 10) is removed, the seed layer 120 of the first via 140 may be exposed. The seed layer 120 of the first via 140 exposed to the outside may be removed by etching. As the seed layer 120 is removed, the first via 140 may have a structure in which the first via 140 is depressed from the first insulating layer 111. In this case, the second via 160 may protect the circuit pattern 150 from an etching process of the seed layer 120. Since the second via 160 is formed on the circuit pattern 150, the second via 160 instead of the circuit pattern 150 may be exposed to the etching process environment. Therefore, when the seed layer 120 is etched, the second via 160 may protect the circuit pattern 150, and the surface of the second via exposed to the outside may be etched. Here, the second via 160 may be etched by the thickness of the seed layer 120.

As described above, the second via 160 is formed on the circuit pattern 150, thereby making it possible to prevent the circuit pattern 150 from being lost by the etching process of the seed metal layer 230, the seed layer 120, and the like. Therefore, the printed circuit board 100 having reliability may be formed by preventing the circuit pattern 150 from being lost.

Through processes shown in FIGS. 10 and 11, the first via 140 depressed by the thickness of the seed layer 120 may be formed on one surface of the printed circuit board 100. In addition, the second via 160 depressed by a sum of the thicknesses of the seed layer 120 and the seed metal layer 230 may be formed on the other surface of the printed circuit board 100. Therefore, depression depths of the first and second vias 140 and 160 may be different from each other by the thickness of the seed metal layer 230.

In the preferred embodiment of the present invention, the case in which the printed circuit board is formed on both surfaces of the carrier board is described by way of example, but the present invention is not limited thereto. The printed circuit board may be formed on only one surface of the carrier board according to the structure of the carrier board and selection by those skilled in the art.

With the printed circuit board and the method of manufacturing the same according to the preferred embodiment of the present invention, the ultra-thin printed circuit board may be formed using the carrier board.

In the printed circuit board and the method of manufacturing the same according to the preferred embodiment of the present invention, the dimple generated at the time of forming the circuit pattern may be prevented.

In the printed circuit board and the method of manufacturing the same according to the preferred embodiment of the present invention, the via is formed on the circuit pattern, thereby making it possible to prevent the circuit pattern from being lost by the etching process.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
an insulating layer;
a first via depressed from one surface of the insulating layer;
a second via depressed from the other surface of the insulating layer; and
a circuit pattern formed in the insulating layer and bonded to the first and second vias.

2. The printed circuit board as set forth in claim 1, wherein the second via is depressed so as to have a depth deeper than that of the first via.

3. The printed circuit board as set forth in claim 1, wherein the first via and the circuit pattern further include a seed layer formed at a side of the first via and a portion contacting the insulating layer on one surface of the circuit pattern bonded to the first via.

4. The printed circuit board as set forth in claim 3, further comprising, wherein the seed layer formed at a bottom of the first via.

5. The printed circuit board as set forth in claim 3, wherein a depression depth of the second via is greater than or equal to a thickness of the seed layer of the first via.

6. The printed circuit board as set forth in claim 1, wherein the insulating layer is made of a photosensitive insulating material.

7. The printed circuit board as set forth in claim 1, wherein the insulating layer is made of a solder resist.

8. The printed circuit board as set forth in claim 1, wherein the first and second vias and the circuit pattern are made of a conductive metal.

9. The printed circuit board as set forth in claim 1, wherein the first via and the circuit pattern are made of a conductive metal, and the second via is formed of a conductive paste.

10. A method of manufacturing a printed circuit board, the method comprising:
forming a first insulating layer including a patterned first via hole on a carrier board;
forming a plating resist including a patterned circuit pattern hole on the first insulating layer;
forming a first via and a circuit pattern on the first via hole and circuit pattern hole using a conductive material;
removing the plating resist;
forming a patterned second insulating layer so that the circuit pattern is embedded therein and the second via hole is positioned on the circuit pattern;
forming a second via on the second via hole using a conductive material; and
removing the carrier board.

11. The method as set forth in claim 10, wherein the first and second insulating layers are made of a photosensitive insulating material.

12. The method as set forth in claim 10, wherein the first and second insulating layers are made of a solder resist.

13. The method as set forth in claim 10, further comprising, after the forming of the first insulating layer, forming a seed layer on the first insulating layer and first via hole.

14. The method as set forth in claim 13, further comprising, after the removing of the plating resist, removing the seed layer exposed by removal of the plating resist.

15. The method as set forth in claim 14, further comprising, after the removing of the carrier board, removing the seed layer exposed by removal of the carrier board.

16. The method as set forth in claim 15, wherein in the removing of the seed layer, the second via is etched to thereby be removed by a thickness greater than or equal to a thickness of the removed seed layer.

17. The method as set forth in claim 16, wherein in the removing of the seed layer, the first via is formed so as to be depressed in the first insulating layer, and the second via is formed so as to be depressed in the second insulating layer.

18. The method as set forth in claim 10, wherein in the forming of the first insulating layer, the first insulating layer is formed on one surface or both surfaces of the carrier board.
